(19) United States
(12) Patent Application Publication
(10) Pub. No.: US 2011/0025454 A1
(43) Pub. Date: Feb. 3, 2011

(54) EMERGENCY MACHINE STOPPING METHOD AND SYSTEM

(76) Inventors: Itzhak POMERANTZ, Kfar Saba (IL); Omri Plotnik, Petah Tikva (IL); Yaniv Shaked, Binyamina (IL)

Correspondence Address: Pearl Cohen Zedek Latzer, LLP, 1500 Broadway, 12th Floor, New York, NY, 10036, US

(21) Appl. No.: 12/512,218

(22) Filed: Jul. 30, 2009

(51) Int. Cl. G05B 19/00; H03K 17/94; H04R 29/00; G05B 23/02

(52) U.S. Cl. 340/3.1; 327/509; 381/56

(57) ABSTRACT

A hybrid emergency stop system, the system includes: (a) a mechanically operated circuit, for stopping an operation of a machine when triggered by a user; and (b) a scream activated circuit, for stopping the operation of the machine when detecting a machine operator scream; wherein the mechanically operated circuit and the scream activated circuit are enclosed in a single compartment and are operable independently from each other.

### FIELD OF THE INVENTION

The invention relates to emergency machine stopping method and system.

### BACKGROUND OF THE INVENTION

Different machines (e.g. industrial and agricultural machines) have—potentially by regulations—an emergency switch that stops the operation of the machine in cases of emergency, typically when a body part of a machine operator is caught by the machine.

These emergency switches are made to be large, visible, accessible and respond to an mechanical trigger applied in different directions, in order to enable an operator of the machine to stop the operation of the machine as fast as possible. Unfortunately, the body part that is most vulnerable to being caught by the machine is the hand, which is the body part needed for activating the emergency switch. Many cases are known in which a worker has been hurt in his hands by the machine, and could not activate the emergency switch. Other cases in which prior art switch are not practical for stopping an operation of a machine are those in which a machine operator is psychologically unable to activate the switch. However, it is very likely that a machine operator that is hurt by a machine will respond by a scream.

FIG. 1 illustrates a prior art one phase emergency stop switch 100 in which an ergonomic cap 110 (illustrated as a mushroom shaped ergonomic cap) is supported in a case 160 and pushed upwards by a spring 112. When a machine operator (or other worker or person) presses on the cap, the bar 180 goes down and breaks the connection between portions of conductor 190 that are otherwise isolated from each other. It should be emphasized that the mechanical switch illustrated in FIG. 1 is built ergonomically to be easily accessed by the reaching hand.

Several attempts were made in the prior art to detect a human scream in noisy environments and to use this detection for stopping machines in emergency. Some of this art can be found in the following:
a. An Acoustic Abnormal Detection System. Hideyuki Masubuchi and Hisato Kobayashi. IEEE International Workshop on Robot and Human Communication. Pgs. 237-242. Discusses how to recognize screams over other noises. Available from IEEE.
b. Scream and Gunshot Detection in Noisy Environments. L. Gerosa, G. Valenzise, M. Tagliasacci, F. Antonacci, and A. Sarti. VISNETT II (a network of excellence funded by the European Commission).
c. Model Based Abnormal Acoustic Source Detection Using a Microphone Array. H. Lee, J. Beh, J. Kim, and H. Ko. Al 2005: Advances in Artificial Intelligence lecture Notes in Artificial Intelligence 3809: 966-969 2005. Focuses on detecting abnormal sounds in an outdoor nature environment. Available from Springer Link
d. Automatic Detection of Stress in Speech. H. J. Fell and J. MacAuslan. MAVEBA 2003.
e. Sentinel Sound Detector Substation built by Jeron Electonic Systems. Monitors intercomms for shouts or screams (like in a hospital/nursing home emergency).

Unfortunately, the prior art solutions, even if they detect the human scream reliably, cannot practically be applied to the installed base of millions of existing machines in the industry, as these old machines are not designed to accommodate a new, sophisticated safety device on board, and the owners of these machine are not likely to afford a re-design of the machines for this purpose.

It would be very desirable to have a method for easy installation of scream-based emergency stop switches in conventional industrial machines without the need to change the wiring or the design of the machine.

### SUMMARY OF THE INVENTION

A hybrid emergency stop system, the system including: (a) a mechanically operated circuit, for stopping an operation of a machine when triggered by a user; and (b) a scream activated circuit, for stopping the operation of the machine when detecting a machine operator scream; wherein the mechanically operated circuit and the scream activated circuit are enclosed in a single compartment and are operable independently from each other.

An emergency stop system, the system including: (a) a first microphone for acquiring machine operator sounds; (b) a second microphone for acquiring machine originated sounds of a machine, wherein the second microphone contacts the machine; (c) a processor configured to process signals obtained from the first and second microphones and to determine when to stop the operation of the machine; and (d) an electrically actuated switch, connected to the processor, for stopping the machine when instructed by the processor.

A method for stopping an operation of a machine, the method including: (a) stopping the operation of the machine if an operator of the machine triggered a mechanically operated circuit; and (b) halting the operation of the machine if a scream activated circuit determined, in response to machine operator sound signal received from a microphone, that a machine operator screamed; wherein the mechanically operated circuit and the scream activated circuit are enclosed in a single compartment.

A method for installing a hybrid emergency stop system, the method including: (a) removing from a machine a mechanically operated emergency stop switch, that is enclosed in an emergency switch housing; and (b) replacing the mechanically operated emergency stop system by a hybrid emergency stop circuit that has a compartment that does not exceed the emergency switch housing; wherein the hybrid emergency stop system includes a mechanically operated circuit, for stopping an operation of a machine when triggered by a user; and a scream activated circuit, for stopping the operation of the machine when detecting a machine operator scream; wherein the mechanically operated circuit and the scream activated circuit are enclosed in a single compartment and are operable independently from each other.

### BRIEF DESCRIPTION OF THE DRAWINGS

The foregoing and other objects, features, and advantages of the present invention will become more apparent from the following detailed description when taken in conjunction with the accompanying drawings. In the drawings, similar reference characters denote similar elements throughout the different views, in which:

FIG. 1 illustrates a prior art one phase emergency stop switch;

FIG. 2 illustrates a hybrid emergency stop system, according to an embodiment of the invention;

FIG. 3 illustrates a hybrid emergency stop system, according to an embodiment of the invention;

FIGS. 4A and 4B illustrate a method for stopping an operation of a machine, according to an embodiment of the invention; and

FIG. 5 illustrates a method for installing a hybrid emergency stop system, according to an embodiment of the invention.

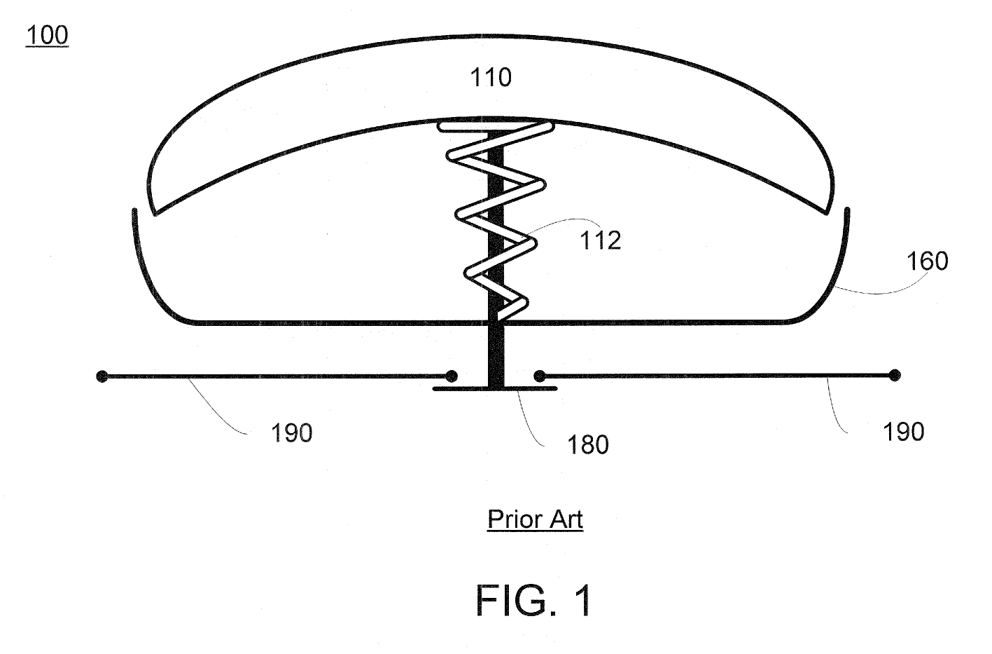

### DETAILED DESCRIPTION OF THE DRAWINGS

The term “scream” includes any loud audio signal generated by a human being. In may include a scream, a holler, a vociferation, a yell, a pounding sound, a loud speech signal, and the like. The audio signal is loud in the sense that it can be heard despite ambient noises generated by the machine. It may be louder than a normal speech signal that is generated by a human.

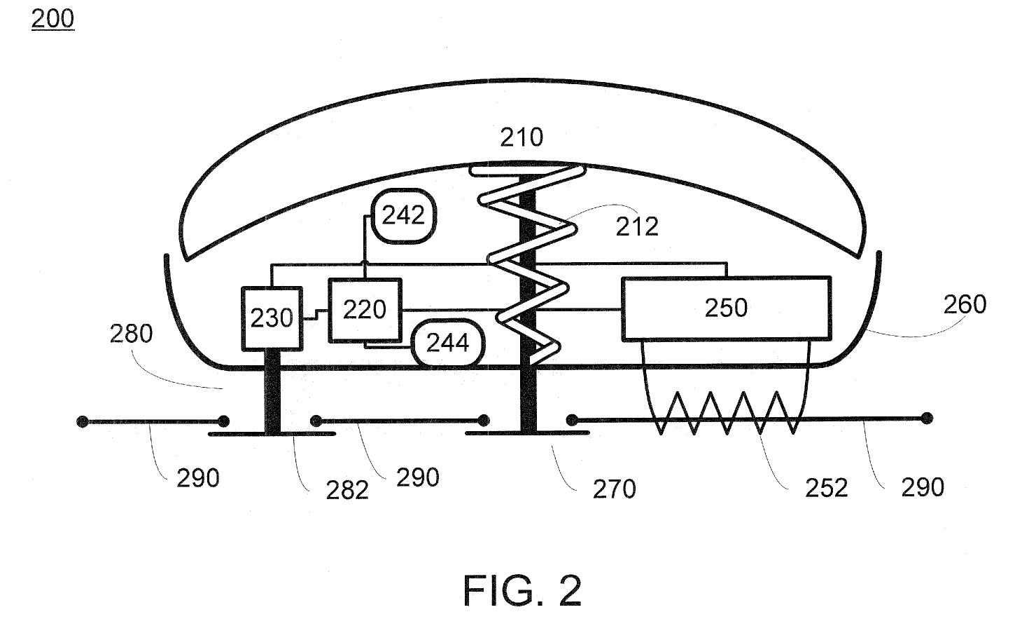

FIG. 2 illustrates hybrid emergency stop system 200, according to an embodiment of the invention. Hybrid emergency stop system 200 is usually installed on an outer surface of a machine which hybrid emergency stop system 200 is used for stopping in emergency cases, or in close proximity to which. It is however noted that hybrid emergency stop system 200 may also be installed elsewhere (e.g. in a central shop floor location) and may be used for the stopping of one part of a machine, or alternatively for the stopping of more than one machine (or parts of machines).

Hybrid emergency stop system 200 includes mechanically operated circuit 270, for stopping an operation of a machine when triggered by a user; and scream activated circuit 280, for stopping the operation of the machine when detecting a machine operator scream; wherein mechanically operated circuit 270 and scream activated circuit 280 are enclosed in a single compartment 260 and are operable independently from each other. It should be noted that while circuits 270 and 280 are illustrated as bars that are operable for breaking connection between portions of conductor 290 that are otherwise isolated from each other, other types (including far more complex types) of circuits (that are operable mechanically or by scream, respectively) may be implemented.

It is noted that, according to an embodiment of the invention, hybrid emergency stop system 200 is of similar size (and possibly shape) to that of a prior art emergency stop switch (such as emergency stop switch 100), so that it is possible to replace an existing prior art emergency stop switch which is already installed in the machine (or elsewhere) with hybrid emergency stop system 200, without any substantial modifications made to the machine itself. It is further noted that, according to an embodiment of the invention, a hybrid emergency stop system 200 may be generated by adding components (and potentially removing others) to an existing prior art emergency stop switch 100.

It is noted that, according to an embodiment of the invention, hybrid emergency stop system 200 includes ergonomic cap 210 (illustrated as a mushroom shaped ergonomic cap) that is supported in a compartment (or casing) 260 and which is pushed upwards by a spring 212. When a machine operator (it is noted that the term machine operator, throughout the description, may be extended to refer to other worker or person) presses on cap 210, the bar 280 goes down and breaks the connection between portions of conductor 290 that are otherwise isolated from each other. It is noted that, according to an embodiment of the invention, mechanically operated circuit 270 includes means (or is connected to means) which prevent a restarting of an operation of the machine without a resetting of hybrid emergency stop system 200 (e.g. a “turn to release” mechanism).

According to an embodiment of the invention, scream activated circuit 280 includes processor 220 that is configured to process machine operator sounds obtained by at least one first microphone 242, and to determine when to stop the operation of the machine. It is noted that any of the at least one first microphones 242 may be included within single compartment 260 or external to it, and that processor 220 and a first microphone 242 may be connected either wirelessly or by wire.

Thus, according to an embodiment of the invention, a first microphone 242 is detachably attachable to a wear of a machine operator, wherein the first microphone 242 transmits the machine operator sounds to the processor wirelessly. Such an installation usually enables a much lesser background noise to be detected by that first microphone 242 (it is distant from the machine) and much clearer reception of the machine operator sound (as first microphone 242 is much closer to the machine operator). It is noted that according to such an embodiment of the invention, the first microphone 242 (as well as wired or wireless communication components not illustrated) may be incorporated into a name tag of the machine operator, into hard-hats that are wore on the shop floor, or into other gear regularly wore or carried by machine operators of the machine.

Clearly, scream operated circuit may include (or be connected to) more than one first microphones 242, e.g. a main first microphone 242 incorporated within the single compartment 260 of hybrid emergency stop system 200, as well as external one or more wireless first microphones 242 that connect with processor 220 wirelessly.

It is clear to a person who is skilled in the art that hybrid emergency stop system 200 may be used in noisy environments (e.g. industrial manufacturing machine, combine harvesters, and other types of agriculture machinery, and so forth). Thus, the at least one first microphone 242 may pick up not only machine operator sounds, but also background noise, which, especially in noisy environments, may interfere with the proper reception of clear machine operator sound.

According to an embodiment of the invention, processor 220 is further configured to process the machine operator sounds (acquired by first microphone 242) and machine originated sounds that are obtained by at least one second microphone 242, for determining when to stop the operation of the machine; wherein the at least one second microphone 244 contacts the machine. Having a second microphone 244 directly contacting a part of the machine (or being in immediate proximity to which) enables to get a clear sample of machine originated sounds, and to process the sound signal detected by first microphone 242 while removing impacts of machine originated sounds. It is noted that other microphones may transfer to processor 220 noises from other noise sources (e.g. adjacent machines in a factory).

It is noted that a second microphone 244 may not be required in different types of machine. For example, some machines—while hazardous—are relatively not noisy. E.g. machines whose operation is based on electronic or chemical process may not be noisy, yet being very dangerous.

Referring to the stopping of the machine by scream activated circuit 280, it is noted that processor 220 is usually adapted to process sound signals received from one or more microphones, as discussed above, and to detect patterns of human scream (and potentially other types of exclamations and/or commands). When such a scream or exclamation is detected, the processor usually actuates one or more other component of scream activated circuit 280 for stopping the machine.

According to an embodiment of the invention, scream activated circuit 280 includes contactor 230 for breaking a conductance of a conductor 290 (which is usually a power transmission line of the machine), wherein processor 220 is further configured to selectively activate contactor 230 for stopping the operation of the machine (e.g. by pushing the bar denoted 282 and thus breaking the conductance of conductor 290).

It is noted that, according to an embodiment of the invention, at least some of the components of scream activated circuit 280 are powered by energy induced from a conductor of mechanically operated circuit 270, wherein the conductor is in close proximity to a circuit breaking point operated by mechanically operated circuit 270.

According to an embodiment of the invention, power supply 250 is fed by a weak AC current that is picked by coil 252 around the conductor 290—when the machine is operating and AC current flows through conductor 290. Having the power for the operation of scream activated circuit 280 picked up this way, according to such an embodiment of the invention, while not essential, serves the purpose of a one-to-one replacement by hybrid emergency stop system 200 of an existing prior art emergency stop switch. According to an embodiment of the invention, the output of power supply unit 250 is DC power.

According to an embodiment of the invention, the DC power of power supply unit 250 is also used to charge a capacitor in contactor 230. The contactor 230 gets a command from processor 220 to break the conductance of conductor 290 if processor 220 detects a scream. Contactor 230 then uses the DC charge accumulated in the capacitor to activate the bar 282 (or otherwise) to break the connectivity of conductor 290.

It is noted that a power supply unit 250 may include an independent power source (e.g. a battery), and may receive source from an auxiliary source (e.g. AC current from standard electrical infrastructure). Power supply unit 250 may include at least one transformer or other device to ensure that power reaches the components of the system at the correct voltage and/or frequency.

It is noted that scream activated circuit 280 (and especially processor 220) may implement different signal processing techniques, many of which are known in the art, for the discerning of a scream pattern in the sound signals information received from the one or more microphone acting as sources.

According to an embodiment of the invention, scream activated circuit 280 is configured to detect pre-determined screams. According to an embodiment of the invention, scream operated circuit 280 (and especially processor 220) is trained to recognize a specific exclamation as a scream. This may be done, for example, on-site, while having the machine and/or adjacent machines operating.

It is noted that the pre-determined scream or exclamation (e.g. “STOP! STOP!”, or “HELP! HELP!”) may pertain to one or more individual workers, or be general.

Processor 220 may be trained to detect pre-determined screams of specific machine operators, either on-site or not.

According to an embodiment of the invention, scream operated circuit 280 (and especially processor 220) is trained to recognize a periodic audio signal as noise. Since operation noise of many machines tends to be generally of a repetitive nature (or a set of several repetitive sounds), scream operated circuit 280 may be trained to ignore such voices (either generally removing noise of recurring nature, or being trained to remove a repetitive sound originating in the environment of operation).

As aforementioned, according to some embodiments of the invention, hybrid emergency stop system 200 may replace an older existing emergency switch, and as such may be subject to physical dimensions limitations, so as to fit within a place formerly occupied by the prior art emergency switch. Different hybrid emergency stop systems 200 may be manufactured to fit different type of prior art emergency switch (e.g. a 1.5″×1.5″ casing, a 2.5″×2.5″ casing, and so forth). According to an embodiment of the invention, the single compartment size (e.g. the size of casing 260) does not exceed 10^{x}10^{x}10 cm³.

It is noted that the accuracy of the scream activated circuit 280, in terms of false detection and misses, can be enhanced, according to different embodiments of the invention, by using any of the following methods:
a. Teaching the machine operator, and training scream activated circuit 280, for a specific exclamation such as “Stop!!” or “Halt!!”
b. Distributing several hybrid emergency stop systems 200 around the machine.

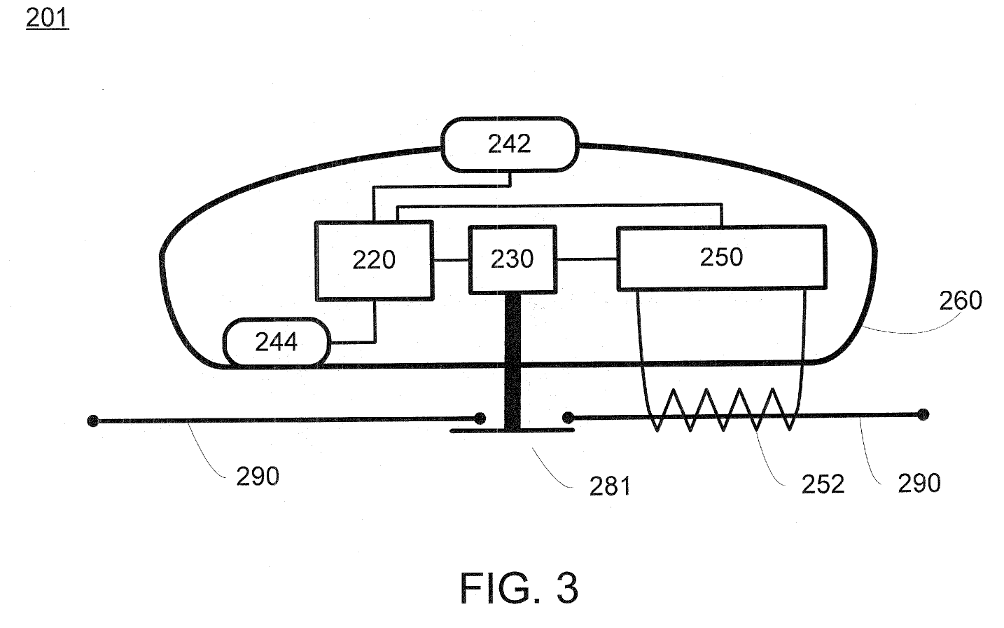

FIG. 3 illustrates emergency stop system 201, according to an embodiment of the invention. Hybrid emergency stop system 201 includes at least one first microphone 242 (which may be internal or external to a casing of hybrid emergency stop system 201), for acquiring machine operator sounds; and may and may not include a second microphone 242 for acquiring machine originated sounds of a machine, wherein the second microphone contacts the machine or in proximity thereto.

Emergency stop system 201 further includes processor 220 for processing signals obtained from the at least one first microphone 242, and from at least one second microphones 244 and for determining when to stop the operation of the machine in response to a result of the processing.

Emergency stop system 201 further includes electrically actuated switch 281, connected to processor 220, for stopping the machine when instructed by the processor. It is noted that some of the embodiments of hybrid emergency stop system 201 includes additional components and/or functionalities such as those discussed in relation to hybrid emergency stop system 200.

According to an embodiment of the invention, emergency stop system is independent of a mechanical emergency switch. According to an embodiment of the invention, processor 220 is configured to process the signals obtained from the respective one or more microphones, to detect a pre-determined scream or pattern, and/or a specific exclamation, and to determine to stop the operation of the machine when such exclamation, pattern, and/or scream is detected.

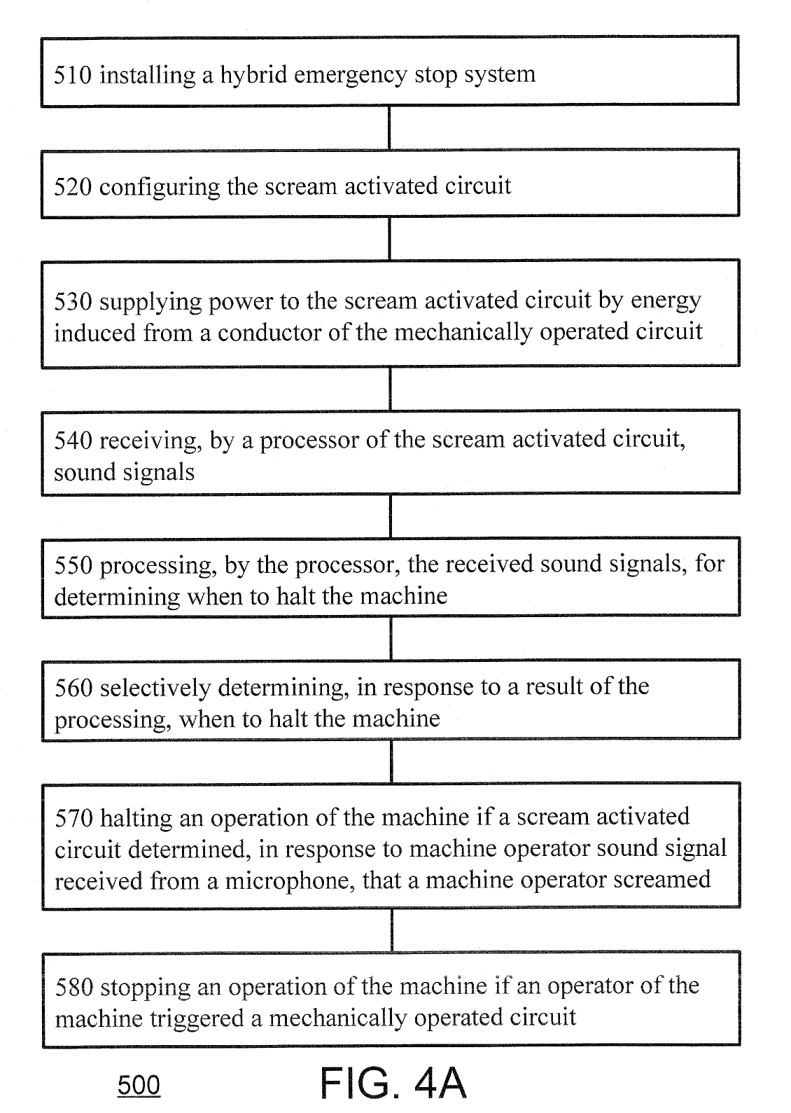

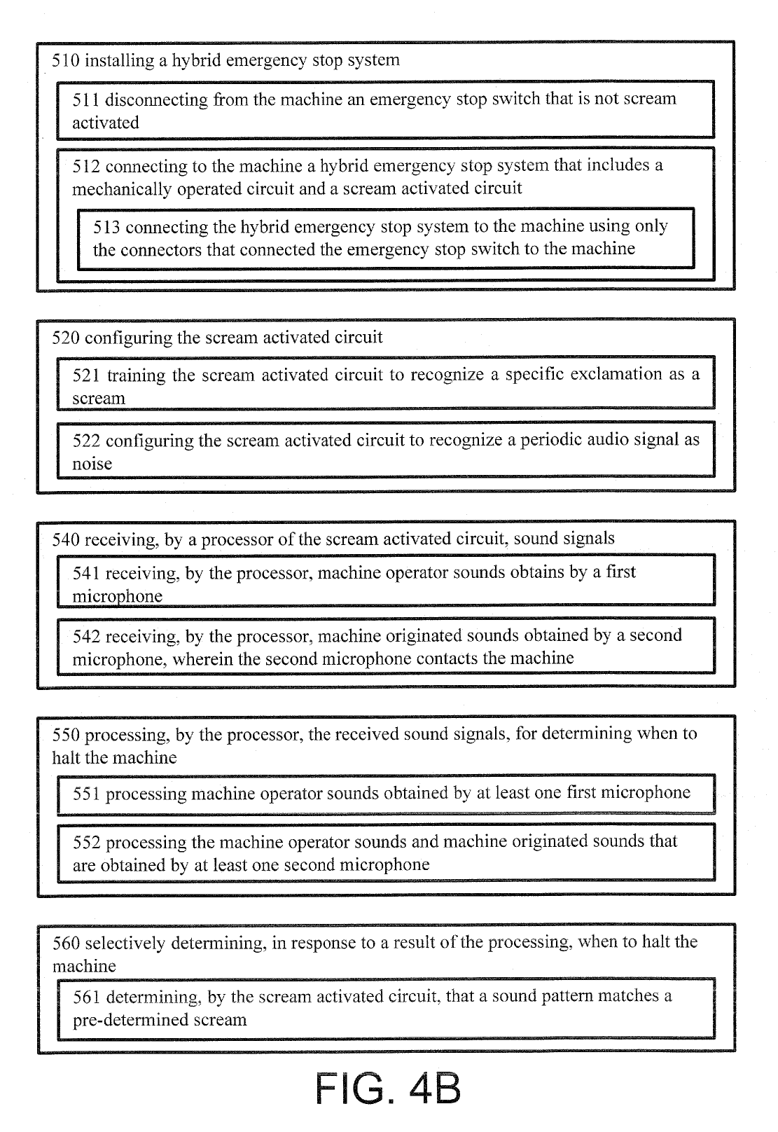

FIG. 4A illustrates method 500 for stopping an operation of a machine, according to an embodiment of the invention, and FIG. 4B illustrates stages of method 500, according to various embodiments of the invention. Referring to the example set forward in the previous drawings, method 500 may be implemented, according to an embodiment of the invention, by hybrid emergency stop system 200.

According to an embodiment of the invention, method 500 starts with stage 510 of installing a hybrid emergency stop system, which includes a mechanically operated circuit for stopping a machine when triggered by a machine operator, and a scream activated circuit for halting the machine when detecting a scream of the machine operator. It is clear that such a hybrid emergency stop system offers a significantly safer work space, as the machine operator have more options for stopping the machine comparing to prior art emergency stop switches, and all the more so as the additional means for stopping the machine are scream activated—when screaming is the most instinctive response in a case of emergency.

It is noted that the mechanically operated circuit and the scream activated circuit of method 500 are enclosed in a single compartment and are operable independently from each other

Stage 510 may include stage 511 of disconnecting from the machine an emergency stop switch that is not scream activated, and stage 512 connecting to the machine a hybrid emergency stop system that includes a mechanically operated circuit and a scream activated circuit. According to an embodiment of the invention, the connecting may include stage 513 of connecting the hybrid emergency stop system to the machine using only the connectors (physical and/or electrical) that connected the older emergency stop switch to the machine. In this way not only there is no need for replacing or adapting considering parts of an existing machine, the replacing itself is very simple, and the machine operator find the mechanically operated circuit (e.g. emergency stop button connected thereto) in the same place where he was trained to use it.

Once installed, the hybrid emergency stop system may be used for stopping the operation of the machine in either manual manner (e.g. following a pressing of an agronomical cap of the mechanically operated circuit by a machine operator) or in a scream activated manner (e.g. once the scream activated circuit detected a scream pattern). However, for greater adaptivity, the scream activated circuit could be configured (in stage 520) to treat different kinds of sound signals.

According to an embodiment of the invention, stage 520 of configuring the scream activated circuit includes stage 521 of training the scream activated circuit to recognize a specific exclamation as a scream. This may be done, for example, on-site, while having the machine and/or adjacent machines operating. This may also be done prior to manufacturing, during a programming of a processor of the scream activated circuit.

According to an embodiment of the invention, stage 520 includes stage 522 of configuring the scream activated circuit to recognize a periodic sound signal as noise. It is noted that the periodic sound signal may only be part (usually distinguishable) of a detected sound signal.

According to an embodiment of the invention, method 500 further includes stage 530 of supplying power to the scream activated circuit by energy induced from a conductor of the mechanically operated circuit, wherein the conductor is usually in close proximity to a circuit breaking point operated by the mechanically operated circuit.

The scream activated circuit usually continuously analyzes and/or processes sound signals obtained by one or more microphones, for determining when to halt the machine (i.e. when a scream is heard).

According to an embodiment of the invention, method 500 includes stage 540 of receiving by a processor of the scream activated circuit, sound signals obtained by one or more microphones.

According to an embodiment of the invention, stage 540 includes stage 541 of receiving, by the processor, machine operator sounds obtained by a first microphone. It is however noted that the first microphone may be included within the single compartment or external to each, in which case method 500 may include transmitting machine operator sounds by the first microphone wirelessly.

According to an embodiment of the invention, stage 540 includes stage 542 of receiving, by the processor, machine originated sounds obtained by a second microphone, wherein the scone microphone contacts the machine, or is closely proximate thereto.

The receiving of the sound signals is followed by stage 550 of processing, by the processor of the scream activated sound signals, the received sound signals, usually for detecting scream pattern.

According to an embodiment of the invention, stage 550 includes stage 551 of processing machine operator sounds obtained by one or more first microphones, an according to an embodiment of the invention, stage 550 includes stage 552 of processing the machine operator sounds obtained by the one or more first microphones, and machine originated sounds that are obtained by one or more second microphones. It is noted that when stage 552 is carried out, usually machine originated sounds are subtracted from the sound signal received from a first microphone, thus obtaining better signal to noise ration.

Stage 550 is followed by stage 560 of selectively determining, in response to one or more result of the processing, when to halt the machine. According to an embodiment of the invention, stage 560 includes stage 561 of determining, by the scream activated circuit, that a sound pattern matches a pre-determined scream.

Method 500 continues with stage 570 of halting the operation of the machine if the scream activated circuit determined, in response to machine operator sound signal received from a microphone, that a machine operator screamed.

Method 500 further includes stage 580 of stopping an operation of the machine if an operator of the machine triggered a mechanically operated circuit wherein the mechanically operated circuit and the scream activated circuit are enclosed in a single compartment. It is noted that stage 580 may be carried out independently of the carrying out of stages 570 (and stages 520 through 560 preceding it), thus ensuring an alternative way for stopping the operation of the machine.

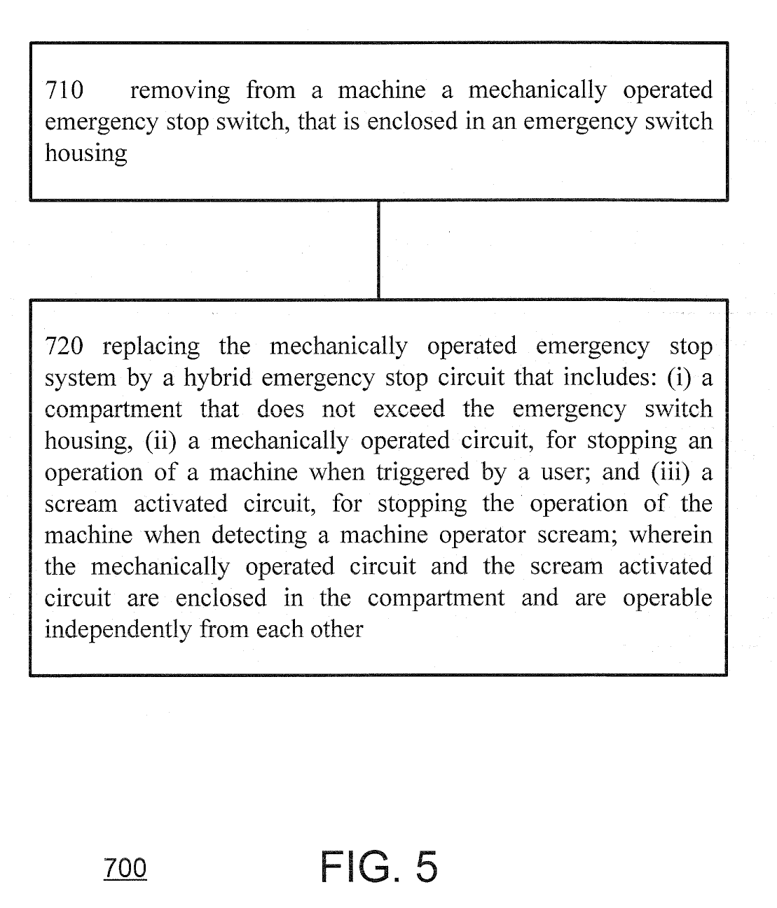

FIG. 5 illustrates method 700 for installing a hybrid emergency stop system, According to an embodiment of the invention.

Method 700 starts with stage 710 of removing from a machine a mechanically operated emergency stop switch, that is enclosed in an emergency switch housing.

Stage 710 is followed by stage 720 of replacing the mechanically operated emergency stop system by a hybrid emergency stop circuit that has a compartment that does not exceed the emergency switch housing, wherein the hybrid emergency stop system includes: a mechanically operated circuit, for stopping an operation of a machine when triggered by a user; and a scream activated circuit, for stopping the operation of the machine when detecting a machine operator scream; wherein the mechanically operated circuit and the scream activated circuit are enclosed in a single compartment and are operable independently from each other.

The present invention can be practiced by employing conventional tools, methodology, and components. Accordingly, the details of such tools, components, and methodology are not set forth herein in detail. In the previous descriptions, numerous specific details are set forth, in order to provide a thorough understanding of the present invention. However, it should be recognized that the present invention might be practiced without resorting to the details specifically set forth.

Only exemplary embodiments of the present invention and but a few examples of its versatility are shown and described in the present disclosure. It is to be understood that the present invention is capable of use in various other combinations and environments and is capable of changes or modifications within the scope of the inventive concept as expressed herein.

We claim:

1. A hybrid emergency stop system, the system comprising:
a mechanically operated circuit, for stopping an operation of a machine when triggered by a user; and
a scream activated circuit, for stopping the operation of the machine when detecting a machine operator scream,
wherein the mechanically operated circuit and the scream activated circuit are enclosed in a single compartment and are operable independently from each other.

2. The system according to claim 1, wherein the scream activated circuit is configured to detect pre-determined screams.

3. The system according to claim 1, wherein the scream activated circuit is powered by energy induced from a conductor of the mechanically operated circuit, wherein the conductor is in close proximity to a circuit breaking point operated by the mechanically operated circuit.

4. The system according to claim 1, wherein the scream activated circuit comprises a processor configured to process machine operator sounds obtained by a first microphone, and for determining when to stop the operation of the machine.

5. The system according to claim 4, wherein the scream activated circuit further comprises a contactor for breaking a conductance of a power transmission line of the machine, wherein the processor is further configured to selectively activate the contactor for stopping the operation of the machine.

6. The system according to claim 4, wherein the processor is further configured to process the machine operator sounds and machine originated sounds that are obtained by a second microphone, for determining when to stop the operation of the machine; wherein the second microphone contacts the machine.

7. The system according to claim 4, wherein the first microphone is detachably attachable to a wear of a machine operator, wherein the first microphone transmits the machine operator sounds to the processor wirelessly.

8. The system according to claim 1, wherein the scream operated circuit is trained to recognize a periodic audio signal as noise.

9. The system according to claim 1, wherein the single compartment size does not exceed 10^{x}10^{x}10 cm³.

10. An emergency stop system, the system comprising:
a first microphone for acquiring machine operator sounds;
a second microphone for acquiring machine originated sounds of a machine, wherein the second microphone contacts the machine;
a processor configured to process signals obtained from the first and second microphones and to determine when to stop an operation of the machine; and
an electrically actuated switch, coupled to the processor, for stopping the machine when instructed by the processor.

11. A method for stopping an operation of a machine, the method comprising:
providing a mechanically operated circuit and a scream activated circuit that are enclosed in a single compartment;
stopping the operation of the machine if an operator of the machine triggered the mechanically operated circuit; and
halting the machine if the scream activated circuit determined that a machine operator screamed, based on received machine operator sound signals.

12. The method according to claim 11, wherein the halting is preceded by determining, by the scream activated circuit, that a sound pattern matches a pre-determined scream.

13. The method according to claim 11, further comprising supplying power to the scream activated circuit by energy induced from a conductor of the mechanically operated circuit, wherein the conductor is in close proximity to a circuit breaking point operated by the mechanically operated circuit.

14. The method according to claim 11, wherein the halting is preceded by processing machine operator sounds obtained by a first microphone, and by selectively determining, in response to a result of the processing, when to halt the machine.

15. The method according to claim 14, wherein the processing further comprises processing the machine operator sounds and machine originated sounds that are obtained by a second microphone, for determining when to halt the machine; wherein the second microphone contacts the machine.

16. The method according to claim 14, further comprising transmitting machine operator sounds by the first microphone wirelessly.

17. The method according to claim 11, wherein the halting is preceded by configuring the scream activated circuit to recognize a periodic audio signal as noise.

18. The method according to claim 11, wherein the stages of stopping and halting are preceded by disconnecting from the machine an emergency stop switch that is not scream activated, and coupling to the machine a hybrid emergency stop system that comprises the mechanically operated circuit and the scream activated circuit.

19. The method according to claim 18, wherein the coupling comprises coupling the hybrid emergency stop system to the machine using only the connectors that coupled the emergency stop switch to the machine.

20. A method for installing a hybrid emergency stop system, the method comprising:
removing from a machine a mechanically operated emergency stop switch that is enclosed in an emergency switch housing;
replacing the mechanically operated emergency stop system by a hybrid emergency stop circuit that comprises:
a compartment that does not exceed the emergency switch housing;
a mechanically operated circuit, for stopping an operation of a machine when triggered by a user; and
a scream activated circuit, for stopping the operation of the machine when detecting a machine operator scream, wherein the mechanically operated circuit and the scream activated circuit are enclosed in the compartment and are operable independently from each other.
